(19) United States
(12) Patent Application Publication
(10) Pub. No.: US 2011/0232953 A1
(43) Pub. Date: Sep. 29, 2011

(54) CIRCUIT BOARD AND STRUCTURE USING THE SAME

(75) Inventors: Takeshi Oga, Yasu (JP); Katsura Hayashi, Yasu (JP)

(73) Assignee: KYOCERA CORPORATION, Kyoto (JP)

(21) Appl. No.: 13/074,144

(22) Filed: Mar. 29, 2011

(30) Foreign Application Priority Data
Mar. 29, 2010 (JP) 2010-074397
Mar. 29, 2011 (JP) 2011-072827

(51) Int. Cl. H05K 1/02

(52) U.S. Cl. 174/258

(57) ABSTRACT

According to one embodiment of the invention, a circuit board comprises an insulating layer including a resin material, a plurality of inorganic insulating particles, and a penetrating hole. The circuit board further comprises a penetrating conductor disposed in the penetrating hole. The insulating layer includes a resin insulating portion having the plurality of inorganic insulating particles dispersed in the resin material. The insulating layer further includes an inorganic insulating portion interposed between the resin insulating portion and the penetrating conductor and made of the same material as the plurality of inorganic insulating particles.

### BACKGROUND OF THE INVENTION

1. Field of the Invention

The present invention relates to a circuit board used in electronic devices (such as various kinds of audio visual devices, household electric devices, communication devices, computers, or their peripheral devices), and a structure using the same.

2. Description of the Related Art

Conventionally, a structure in which an electronic component is mounted to a circuit board is used as a structure in an electronic device.

Regarding the circuit board, Japanese Patent Application Laid-Open No. 2003-101183 discloses a configuration including an insulating layer composed of an inorganic filler and an insulating resin, and a plated layer adhering to an inner wall of a through hole penetrating the insulating layer.

When an electric field is applied between the adjacent through holes, a conductive material contained in the plated layer is ionized by water in the resin and could enter the insulating layer and reach the plated layer of the adjacent through hole (ion migration).

Especially, when the inorganic filler and the insulating resin are contained in the insulating layer, the inorganic filler is sometimes separated from the insulating resin, and water is likely to be accumulated in this separated part, so that the above ionized conductive material is likely to elongate in the separated part.

When the conductive material enters the insulating layer and reaches the plated layer of the adjacent through hole, a short circuit is caused between the plated layers of the adjacent through holes, and electric reliability of the circuit board is lowered. Therefore, it is required to improve insulating properties between the through holes.

### BRIEF SUMMARY OF THE INVENTION

The present invention provides a circuit board and a structure using the same to meet a requirement for improving electrical reliability.

According to one embodiment of the invention, a circuit board comprises

an insulating layer including a resin material, a plurality of inorganic insulating particles, and a penetrating hole. The circuit board further comprises

a penetrating conductor disposed in the penetrating hole. The insulating layer includes a resin insulating portion having the plurality of inorganic insulating particles dispersed in the resin material. The insulating layer further includes an inorganic insulating portion interposed between the resin insulating portion and the penetrating conductor and made of the same material as the plurality of inorganic insulating particles.

According to another embodiment of the invention, a structure comprises the circuit board and an electronic component electrically connected to the circuit board.

### BRIEF DESCRIPTION OF THE DRAWINGS

FIG. 1 is a cross-sectional view of a structure according to one embodiment of the present invention taken along a thickness direction;

FIG. 2A is an enlarged view of a part R1 in FIG. 1, and FIG. 2B is a view of a surface in a first inorganic insulating portion 7a2 on the side of a first penetrating conductor 8a in FIG. 2(a);

FIG. 3A is an enlarged view of a part R2 in FIG. 1, and FIG. 3B is a view of a surface in a second inorganic insulating portion 7b2 on the side of a second penetrating conductor 8b in FIG. 3A;

FIGS. 4A and 4B are cross-sectional views cut in a thickness direction to explain steps of producing the structure shown in FIG. 1, and FIG. 4C is an enlarged view of a part R3 in FIG. 4B; and

FIGS. 5A and 5B are cross-sectional views cut in a thickness direction to explain steps of producing the structure shown in FIG. 1.

### DETAILED DESCRIPTION OF EXEMPLARY EMBODIMENTS

Hereinafter, a structure including a circuit board according to one embodiment of the present invention is described in detail with reference to the drawings.

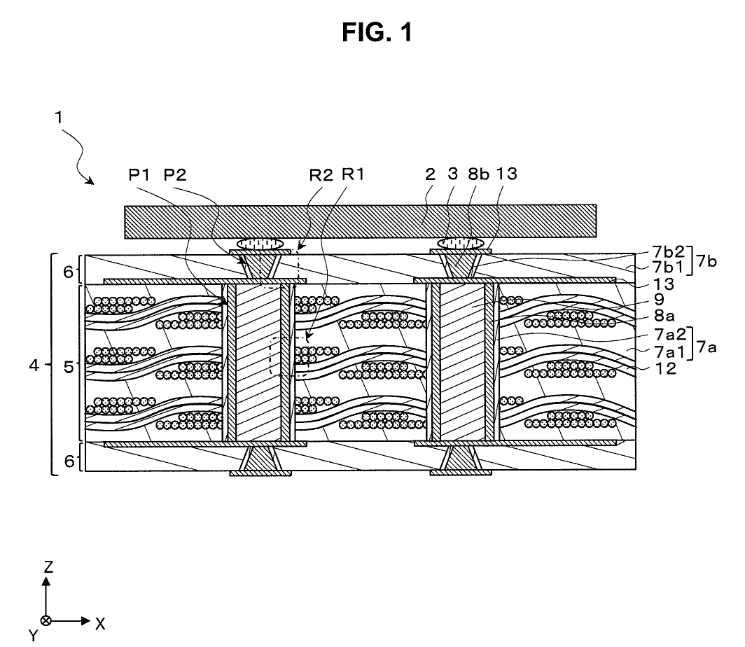

A structure 1 shown in FIG. 1 is used in electronic devices such as various kinds of audio visual devices, household electric devices, communication devices, computers, or their peripheral devices. This structure includes an electronic component 2, and a plate-shaped circuit board 4 on which the electronic component 2 is mounted by flip chip bonding through a bump 3.

The electronic component 2 is a semiconductor element such as IC or LSI, and its base material is a semiconductor material such as silicon, germanium, gallium arsenide, gallium arsenide phosphide, gallium nitride, or silicon carbide. A thickness of the electronic component 2 is set at 0.1 mm to 1 mm, and thermal expansion rates thereof in a planar direction (X-Y planar direction) and a thickness direction (Z direction) of the circuit board 4 are set at 3 ppm/° C. to 5 ppm/° C., and a Young's modulus thereof is set at 50 GPa to 200 GPa.

The thickness is measured by cutting a sample in a thickness direction, observing its polished surface or fracture surface with a scanning electron microscope, measuring lengths in the thickness direction at ten or more points, and calculating their average value. The thermal expansion rate is measured with a commercially available TMA device by a measurement method in conformity with JISK7197-1991. The Young's modulus is measured with a Nano Indenter XP/DCM produced by MTS Systems Corporation.

Those measuring methods are applicable to other elements, such as a circuit board, first and second insulating layers described below, or the like.

The bump 3 is composed of a conductive material such as solder containing lead, tin, silver, gold, copper, zinc, bismuth, indium, or aluminum.

The circuit board 4 includes a plate-shaped core board 5, and a pair of buildup parts 6 formed on both sides of the core board 5. A thickness of the circuit board 4 is set at 0.2 mm to 1.2 mm, thermal expansion rates thereof in a planar direction is set at 5 ppm/° C. to 30 ppm/° C. and in a thickness direction is set at 15 ppm/° C. to 50 ppm/° C., that is, the thermal expansion rate in the thickness direction is set to be 1.5 times to 3 times as high as the thermal expansion rate in the planar direction, and a Young's modulus thereof is set at 5 GPa to 30 GPa.

The core board 5 is provided to enhance strength of the circuit board 4 and connect the pair of buildup parts 6, and includes a first plate-shaped insulating layer 7a in a plate shape in which first penetrating holes P1 penetrating in the thickness direction are formed, a cylindrical first penetrating conductor 8a formed in the first penetrating hole P1, and an insulator 9 in a column shape formed in the first penetrating conductor 8a. A thickness of the core board 5 is set at 0.1 mm to 1.0 mm.

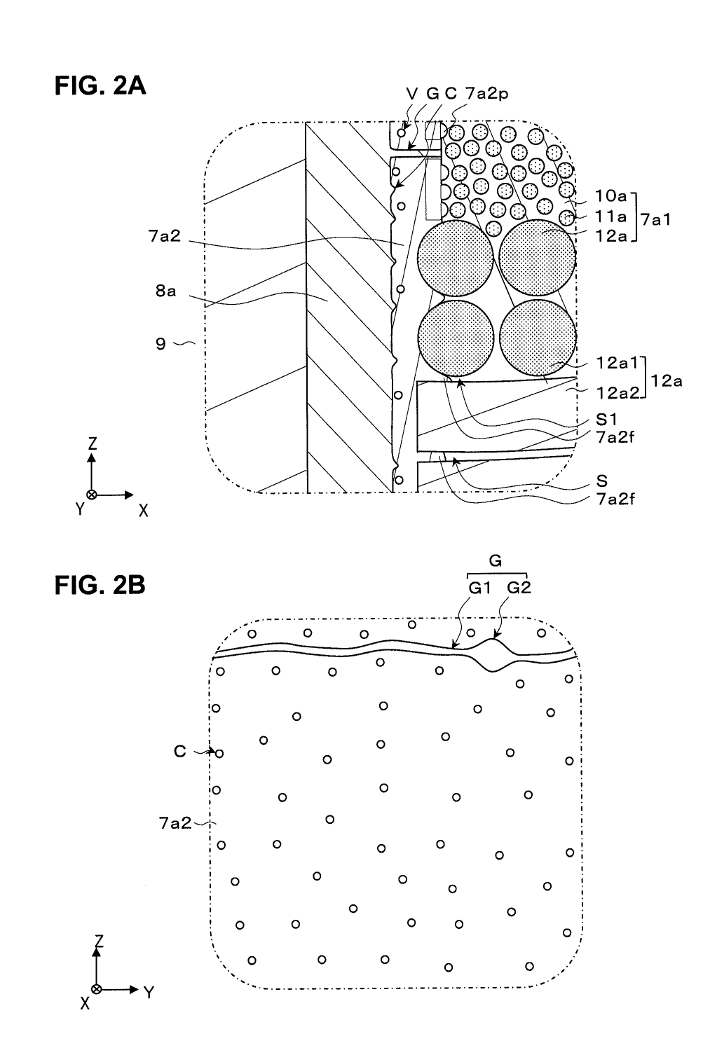

The first insulating layer 7a serves as a main part in the core board 5 to enhance rigidity, and as shown in FIGS. 1 and 2A includes a first resin material 10a, first inorganic insulating particles 11a, and a fiber material 12. The first insulating layer 7a has a first resin insulating portion 7a1 and first inorganic insulating portions 7a2. The first resin insulating portion 7a1 has the first inorganic insulating particles 11a (shown in FIG. 2A) dispersed in the first resin material 10a and the fiber material 12 covered with the first resin material 10a, and the first inorganic insulating portion 7a2 is formed around an outer surface of the first penetrating conductor 8a to be interposed between the first penetrating conductor 8a and the first resin insulating portion 7a1.

The first resin insulating portion 7a1 serves as a main part in the first insulating layer 7a, and formed into a plate shape. Thermal expansion rates of the first resin insulating portion 7a1 in a planar direction is set at 5 ppm/° C. to 30 ppm/° C. and in a thickness direction is set at 15 ppm/° C. to 50 ppm/° C., that is, the thermal expansion rate in the thickness direction is set to 1.5 times to 3 times as high as the thermal expansion rate in the planar direction, and a Young's modulus thereof is set at 5 GPa to 30 GPa.

The first resin material 10a contained in the first resin insulating portion 7a1 serves as a main part in the first insulating layer 7a, and may be made of a resin material such as epoxy resin, bismaleimide triazine resin, cyanate resin, poly(p-phenylenebenzobisoxazole) resin, wholly aromatic polyamide resin, polyimide resin, aromatic liquid crystal polyester resin, polyether ether ketone resin, or polyether ketone resin. Thermal expansion rates of the first resin material 10a in planar and thickness directions are set at 20 ppm/° C. to 50 ppm/° C., and a Young's modulus thereof is set at 0.1 GPa to 5 GPa.

The first inorganic insulating particles 11a contained in the first resin material 10a constitute an inorganic insulating filler to reduce the thermal expansion rate of the first resin insulating portion 7a1 and enhance the rigidity of the first resin insulating portion 7a1, and may be made of an inorganic insulating material composed mostly of silicon oxide. The inorganic insulating material composed mostly of silicon oxide may contain aluminum oxide, magnesium oxide, calcium oxide, aluminum nitride, aluminum hydroxide, or calcium carbonate. The first inorganic insulating particles 11a preferably contain 65% by weight to 100% by weight of silicon oxide.

The first inorganic insulating particle 11a is formed into a spherical shape and a particle diameter is set at 0.5 μm to 5.0 μm, a content thereof in the first resin material 10a of the first resin insulating portion 7a1 is set at 50% by volume to 85% by volume, and a thermal expansion rate thereof in each direction is set at 0 ppm/° C. to 7 ppm/° C.

The particle diameter of the first inorganic insulating particle 11a is measured by observing a polished surface or fracture surface of the first resin insulating portion 7a1 with a field-emission electron microscope, photographing a cross-section which has been enlarged so as to contain 20 particles to 50 particles, and measuring a maximum diameter of each particle in the enlarged cross-section. The content (% by volume) of the first inorganic insulating particles 11a in the first resin material 10a of the first resin insulating portion 7a1 is measured by photographing the polished surface of the first resin insulating portion 7a1 with the field-emission electron microscope, measuring an area ratio (% by area) of the first inorganic insulating particles 11a of the first resin material 10a of the first resin insulating portion 7a1 in ten cross-sections with an image analysis device, calculating an average value of the measured values, and regarding it as the content (% by volume).

The fiber material 12 covered with the first resin material 10a serves to enhance rigidity of the first resin insulating portion 7a1 and has a thermal expansion rate in a planar direction smaller than that in a thickness direction. Thus, by absorbing a difference in thermal expansion rate in the planar direction between the circuit board 4 and the electronic component 2, warpage of the circuit board 4 can be reduced. This fiber material 12 may be cloth woven by fibers 12a in vertical and horizontal directions, and the fiber 12a may be glass fiber, resin fiber, carbon fiber, or metal fiber, and it is preferably the glass fiber among them.

The first inorganic insulating portion 7a2 adheres to the first resin insulating portion 7a1 to form an inner wall of the first penetrating hole P1, and it is formed into a film composed of the same material as the first inorganic insulating particles 11a. A thickness of the first inorganic insulating portion 7a2 is set at 0.05 μm to 4 μm, and a thermal expansion rate thereof in each direction is set at 1 ppm/° C. to 7 ppm/° C., and Young's modulus thereof is set at 10 GPa to 100 GPa.

The material of the first inorganic insulating portion 7a2 and the first inorganic insulating particles 11a can be measured by calculating weight % of each atom in the first inorganic insulating portion 7a2 and the first inorganic insulating particles 11a using a commercially available EPMA (Electron Probe Microanalyzer) on a cross section of the first insulating layer 7a along a thickness direction. In the present embodiment, in the first inorganic insulating portion 7a2 having the same material as the first inorganic insulating particles 11a, weight % of each atom is 0.97 times to 1.03 times as large as that of each atom in the first inorganic insulating particles 11a. This measurement method is also applicable to the second inorganic insulating portion 7b2 and the second inorganic insulating particles 11b.

The first penetrating conductor 8a penetrates the first insulating layer 7a in the thickness direction, electrically connects the buildup portions 6 provided on the upper and lower sides of the core board 5. The first penetrating conductor 8a is formed along an inner wall of the first penetrating hole P1 and adheres to the first inorganic insulating portion 7a2. The first penetrating conductor 8a may be made of a conductive material such as copper, silver, gold, aluminum, nickel, or chrome. A thickness of the first penetrating conductor 8a is set at 3 μm to 20 μm, a thermal expansion rate thereof in each direction is set at 5 ppm/° C. to 25 ppm/° C., and a Young's modulus thereof is set at 50 GPa to 250 GPa.

The insulator 9 formed in the first penetrating conductor 8a serves as a support surface of a second penetrating conductor 8b which is described below, and may be made of a resin material such as polyimide resin, acrylic resin, epoxy resin, cyanate resin, fluorine resin, silicon resin, polyphenylene ether resin, or bismaleimide triazine resin.

Meanwhile, as described above, the pair of buildup portions 6 is formed on both sides of the core board 5. The buildup portion 6 includes a second insulating layer 7b formed on the first insulating layer 7a and having a plurality of second penetrating holes P2 penetrating in a thickness direction, a conductive layer 13 formed on the first insulating layer 7a or the second insulating layer 7b, and the second penetrating conductor 8b formed in the second penetrating hole P2 and electrically connected to the conductive layer 13.

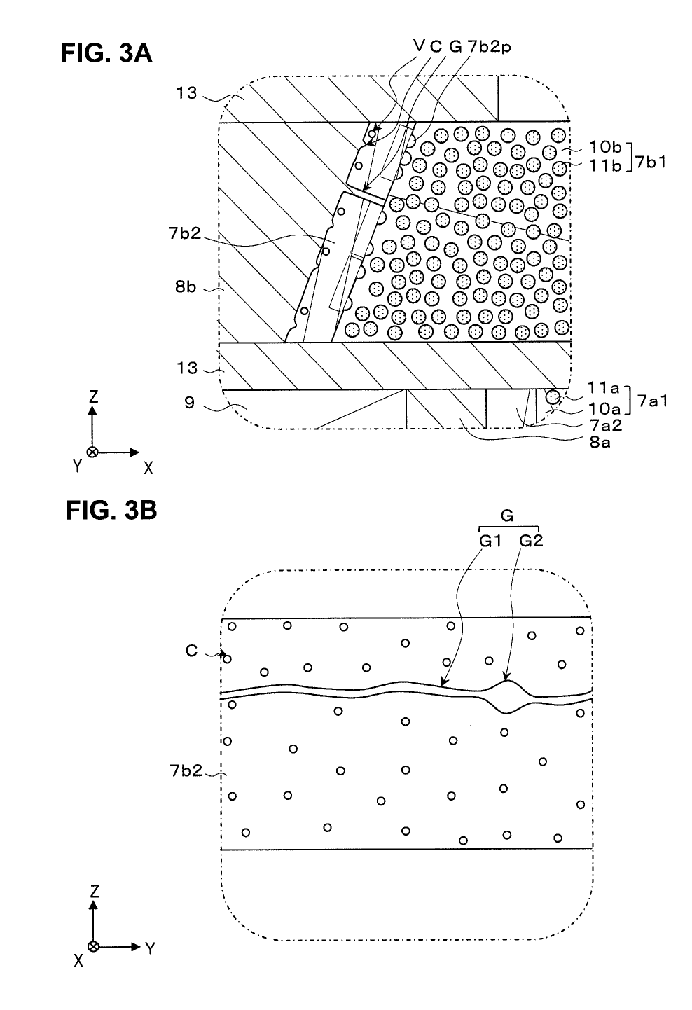

The second insulating layer 7b functions as a support member to support the conductive layer 13, and also functions as an insulating member to prevent a short circuit between the conductive layers 13, and as shown in FIG. 3A, it includes a second resin material 10b and second inorganic insulating particles 11b. The second insulating layer 7b includes a second resin insulating portion 7b1 having the second inorganic insulating particles 11b dispersed in the second resin material 10b, and a second inorganic insulating portion 7b2 interposed between the second resin insulating portion 7b1 and the second penetrating conductor 8b and made of the same material as the second inorganic insulating particles 11b.

The second resin insulating portion 7b1 serves as a main part in the second insulating layer 7b, a thickness thereof is set at 5 μm to 40 μm, thermal expansion rates thereof in a planar direction and a thickness direction are set at 15 ppm/° C. to 45 ppm/° C., and a Young's modulus thereof is set at 5 GPa to 40 GPa.

The second resin material 10b contained in the second resin insulating portion 7b1 may be made of a resin material such as epoxy resin, bismaleimide triazine resin, cyanate resin, poly(p-phenylenebenzobisoxazole) resin, wholly aromatic polyamide resin, polyimide resin, aromatic liquid crystal polyester resin, polyether ether ketone resin, or polyether ketone resin.

The second inorganic insulating particles 11b contained in the second resin material 10b may be made of the same material as that of the first inorganic insulating particles 11a contained in the first insulating layer 7a. Among them, since the thickness of the second resin insulating portion 7b1 is smaller than that of the first resin insulating portion 7a1, a particle diameter of the second inorganic insulating particle is preferably set at 3.0 μm or less.

The second inorganic insulating portion 7b2 adheres to an inner wall of the second resin insulating portion 7b1 provided around the second penetrating hole P2, and it is formed into a film composed of the same material as the second inorganic insulating particles 11b. A thickness of the second inorganic insulating portion 7b2 is set at 0.05 μm to 2 μm, a thermal expansion rate thereof in each direction is set at 1 ppm/° C. to 7 ppm/° C., and a Young's modulus thereof is set at 10 GPa to 100 GPa.

The conductive layers 13 are arranged on the first insulating layer 7a and on the second insulating layer 7b, respectively, and may be made of a metal material such as copper, silver, gold, aluminum, nickel, or chrome. A thickness of the conductive layer 13 is set at 3 μm to 20 μm, thermal expansion rates thereof in a planar direction and a thickness direction are set at 5 ppm/° C. to 25 ppm/° C., and a Young's modulus thereof is set at 50 GPa to 250 GPa.

The second penetrating conductor 8b connects the conductive layers 13 apart from each other in the thickness direction, and is formed into a column shape in such a manner that a cross section thereof taken along a planar direction of the circuit board 4 is circular and an area of the cross section decreases toward the core board 5, and it may be made of a conductive material such as copper, silver, gold, aluminum, nickel, or chrome. The cross section of the second penetrating conductor 8b taken along the planar direction of the circuit board 4 is set at 300 μm² to 700 μm², a thermal expansion rate thereof in each direction is set at 7 ppm/° C. to 25 ppm/° C., and a Young's modulus thereof is set at 50 GPa to 250 GPa.

The first penetrating conductor 8a, the conductive layer 13, and the second penetrating conductor 8b are electrically connected to each other to constitute a set of conductive lines. The conductive lines function as grounding lines, power supplying lines, or signal lines.

Thus, since the first penetrating conductor 8a functions as the lines such as the grounding lines, the power supplying lines, or the signal lines, a voltage thereof is sometimes different from that of the adjacent first penetrating conductor 8a, so that an electric field is generated between the adjacent first penetrating conductors 8a in some cases.

Meanwhile, as shown in FIG. 2A, in the circuit board 4 according to this embodiment, the first inorganic insulating portion 7a2 made of the same material as the first inorganic insulating particles 11a is interposed between the first resin insulating portion 7a1 and the first penetrating conductor 8a. Here, the inorganic insulating material of the first inorganic insulating portion 7a2 is composed of molecules of smaller molecular size having a smaller intermolecular space as compared with the resin material and absorbs little water because a water molecule is not likely to enter between the molecules of the inorganic insulating materials, so that the conductive material of the first penetrating conductor 8a is less likely to enter the first inorganic insulating portion 7a2 which has little water for ionization. Therefore, insulating properties between the first insulating layer 7a and the first penetrating conductor 8a can be improved, and electric reliability of the circuit board 4 can be improved.

Since the first inorganic insulating portion 7a2 is formed into a film composed of the same material as the first inorganic insulating particles 11a, the thermal expansion rates thereof in the planar direction and the thickness direction are smaller than those of the first resin insulating portion 7a1 having the first inorganic insulating particles 11a dispersed in the first resin material 10a. Therefore, when the thermal expansion rate of the first resin insulating portion 7a1 in the thickness direction is set to be higher than that of the first penetrating conductor 8a, the first inorganic insulating portion 7a2 can absorb a difference in thermal expansion rate in the thickness direction between the first insulating layer 7a and the first penetrating conductor 8a, so that a crack generated due to the difference in thermal expansion rate can be reduced in the first penetrating conductor 8a in a circumferential direction, and accordingly breaking of the first penetrating conductor 8a can be reduced.

Since the first inorganic insulating particle 11a is composed mostly of silicon oxide, it is superior in electric characteristics such as a dielectric dissipation factor or dielectric constant compared with the first resin material 10a, so that when the first inorganic insulating portion 7a2 made of the same material as the first inorganic insulating particles 11a is interposed between the first resin insulating portion 7a1 and the first penetrating conductor 8a, signal transmission characteristics of the first penetrating conductor 8a can be enhanced.

As shown in FIGS. 2A and 2B, a groove portion G penetrates the first inorganic insulating portion 7a2 from the side of the first penetrating conductor 8a to the side of the first resin insulating portion 7a1 and extends along a circumferential direction of the first penetrating hole P1, and a part of the first penetrating conductor 8a fills in the groove portion G. As a result, an anchor effect in the thickness direction can reduce separation between the first inorganic insulating portion 7a2 and the first penetrating conductor 8a due to the difference in thermal expansion rate in the thickness direction between the first insulating layer 7a and the first penetrating conductor 8a. Therefore, since the separated part where water easily accumulates is reduced, elongation of the conductive material in the separated part is reduced, and insulating properties between the first insulating layer 7a and the first penetrating conductor 8a can be improved. In addition, by reducing the separated part where water easily accumulates, breaking of the first penetrating conductor 8a due to water evaporation and expansion caused when heat is applied to the circuit board 4.

The groove portion G may have a narrow width portion G1 and a wide width portion G2 having a groove width wider than the narrow width portion G1. The groove width is a width of a groove in a penetrating direction of the first penetration hole P1 and a groove length is a length of the groove extending along a circumference of the first penetration hole P1. In this case, when a part of the first penetrating conductor 8a fills in the wide width portion G2, a strong anchor effect is generated in the thickness direction, and separation between the first inorganic insulating portion 7a2 and the first penetrating conductor 8a can be further reduced A groove width of the narrow width portion G1 is set at 0.5 μm to 5 μm, and a groove length thereof is set at 10 μm to 1 mm, and a groove width of the wide width portion G2 is set at 3 μm to 20 μm, that is, the groove width thereof is set to be 2 times to 40 times as long as that of the narrow width portion G1, and a groove length thereof is set at 3 μm to 20 μm, that is, the groove length thereof is set to be 0.03 time to 0.2 time as long as that of the narrow width portion G1.

The first inorganic insulating portion 7a2 has a plurality of concave portions C at the inner wall of the penetrating hole P1, that is, at a first boundary surface of the first inorganic insulating portion 7a2 with the first penetrating conductor 8a, and a part of the first penetrating conductor 8a fills in the concave portions C. As a result, an anchor effect is generated in the planar direction and the thickness direction, and separation between the first inorganic insulating portion 7a2 and the first penetrating conductor 8a due to a difference in thermal expansion rate between the first insulating layer 7a and the first penetrating conductor 8a in the planar direction and the thickness direction can be reduced.

The concave portion C has an opening formed into a circular shape in the first boundary surface. As a result, stress applied to an end portion of the opening can be dispersed and generation of a crack can be reduced.

The concave portions C are arranged so as to be dispersed in the surface of the first boundary surface. As a result, variation in adhesion strength between the first inorganic insulating portion 7a2 and the first penetrating conductor 8a can be reduced.

A diameter of the opening of the concave portion C in the first boundary surface is set at 0.2 μm to 3 μm, and a depth thereof is set at 0.2 μm to 3 μm, and the depth is set to be 0.01 time to 0.2 time as long as the thickness of the first inorganic insulating portion 7a2.

The concave portion C is formed at the first boundary surface and does not penetrate the first inorganic insulating portion 7a2, so that the insulating properties of the first inorganic insulating portion 7a2 can be enhanced as compared with the groove portion G. Meanwhile, the groove portion G penetrates the first inorganic insulating portion 7a2 and extends along the circumferential direction of the first penetrating hole P1, so that the anchor effect can be enhanced between the first inorganic insulating portion 7a2 and the first penetrating conductor 8a in the thickness direction and adhesion strength can be enhanced between the first inorganic insulating portion 7a2 and the first penetrating conductor 8a as compared with the concave portion C. Therefore, the first inorganic insulating portion 7a2 preferably has both of the groove portion G and the concave portion C in order to enhance the insulating properties and the adhesion strength with the first penetrating conductor 8a.

The first inorganic insulating portion 7a2 contains a plurality of voids V. Therefore, even when a crack is generated due to stress applied to the first inorganic insulating portion 7a2 and elongates from the first penetrating conductor 8a to the first resin insulating portion 7a1, elongation of the crack is prevented at the void V because the stress of the crack is dispersed in an inner wall of the void V. As a result, generation of a crack penetrating the first inorganic insulating portion 7a2 from the first penetrating conductor 8a toward the first resin insulating portion 7a1 can be reduced, so that the conductive material of the first penetrating conductor 8a does not enter the first resin insulating portion 7a1 through the crack.

In addition, larger number of the voids V is arranged on the side of the first penetrating conductor 8a than on the side of the first resin insulating portion 7a1. Here, since the void V arranged on the side of the first penetrating conductor 8a is closer to the first penetrating conductor 8a than to the first resin insulating portion 7a1, the crack is less likely to elongate in a region close to the first penetrating conductor 8a. Therefore, even when stress is further applied after the voids V stops elongation of the crack, the crack is less likely to elongate from the void V to the first resin insulating portion 7a1 because there is a large distance between the void V and the first resin insulating portion 7a1. As a result, the crack penetrating the first inorganic insulating portion 7a2 from the first penetrating conductor 8a to the first resin insulating portion 7a1 can be reduced.

The void V is formed into a spherical shape whose diameter is set at 0.2 μm to 3 μm, and filled with gas. In addition, the number of the voids V arranged on the side of the first penetrating conductor 8a is 5 times to 100 times as large as the number of the voids V arranged on the side of the resin insulating portion 7a1, and it is preferable all the voids V are provided on the side of the first penetrating conductor 8a rather than on the side of the first resin insulating portion 7a1.

The first inorganic insulating portion 7a2 has a plurality of protruding portions 7a2p composed of the first inorganic insulating particle 11a, in a second boundary surface of the first inorganic insulating portion 7a2 with the first resin insulating portion 7a1, and the protruding portion 7a2p protrudes into the first resin insulating portion 7a1 and covered with the first resin material 10a. As a result, separation between the first inorganic insulating portion 7a2 and the first resin insulating portion 7a1 due to an anchor effect can be reduced.

The protruding portion 7a2p has the same shape as a part of the first inorganic insulating particle 11a. That is, in the case where the first inorganic insulating particle 11a has the spherical shape, the protruding portion 7a2p has the same shape as a part of the sphere protruding from the second boundary surface. As a result, the first inorganic insulating portion 7a2 can be more strongly connected to the first resin insulating portion 7a1.

A height of the protruding portion 7a2p in the protruding direction is set at 0.5 μm to 3 μm, and a width thereof is set at 0.5 μm to 3 μm.

By the way, when the fiber material 12 is contained in the first resin insulating portion 7a1, in some cases, the fiber 12a is separated from the first resin material 10a by stress generated between the fiber 12a and the first resin material 10a in a longitudinal direction of the fiber 12a because a thermal expansion rate of the fiber 12a in the longitudinal direction is smaller than the thermal expansion rate of the first resin material 10a.

Meanwhile, in the circuit board 4 according to this embodiment, the first inorganic insulating portion 7a2 is interposed between the fiber 12a and the first penetrating conductor 8a. Therefore, the first inorganic insulating portion 7a2 can stop the conductive material of the first penetrating conductor 8a entering a separated part between the fiber 12a and the first resin material 10a, and accordingly can prevent a short circuit between the adjacent first penetrating conductors 8a.

A part of the first inorganic insulating portion 7a2 enters a space S between the adjacent fibers 12a so as to form an embedded portion 7a2f. As a result, the embedded portion 7a2f can reduce the conductive material of the first penetrating conductor 8a entering the space S between the fibers 12a where the fiber 12a is likely to be separated from the first resin material 10a.

The embedded portion 7a2f preferably is in contact with and bonded to the fibers 12a having the space S therebetween. It is more preferable that the embedded portion 7a2f is in contact with and bonded to each of the fibers 12a in the cross section in the thickness direction of the circuit board 4. As a result, the conductive material of the first penetrating conductor 8a is further prevented from entering the space S. Since the fiber 12a is fixed by the embedded portion 7a2f, the fiber 12a becomes less likely to be separated from the first resin material 10a.

The fiber 12a has a first fiber 12a1, and a second fiber 12a2 which is adjacent and perpendicular to the first fiber 12a1, and the embedded portion 7a2f is formed in a space 51 between the first fiber 12a1 and the second fiber 12a2. Here, since the first fiber 12a1 is perpendicular to the second fiber 12a2, stress along the longitudinal direction of the first fiber 12a1 and stress along the longitudinal direction of the second fiber 12a2 are applied to the first resin material 10a between the first fiber 12a1 and the second fiber 12a2, and the first fiber 12a1 or the second fiber 12a2 is likely to be separated from the first resin material 10a. However, since the embedded portion 7a2f is formed in the space S1, the conductive material is less likely to enter the separated part.

The embedded portion 7a2f is preferably in contact with and bonded to each of the first fiber 12a1 and the second fiber 12a2. As a result, since the embedded portion 7a2f fixes the first fiber 12a1 and the second fiber 12a2, the first fiber 12a1 or the second fiber 12a2 is less likely to be separated from the first resin material 10a.

The first inorganic insulating portion 7a2 is preferably formed in the thickness direction and the circumferential direction of the first penetrating hole P1. As a result, the insulating properties between the first penetrating conductor 8a and the first resin insulating portion 7a1 can be enhanced in the thickness direction and the circumferential direction of the first penetrating hole P1.

Furthermore, the thickness of the first inorganic insulating portion 7a2 is set to be smaller than that of the first penetrating conductor 8a. As a result, resistance of the first penetrating conductor 8a can be decreased by increasing the thickness of the first penetrating conductor 8a. In addition, the thickness of the first inorganic insulating portion 7a2 is set to be 0.1 time to 0.8 time as thick as that of the first penetrating conductor 8a.

As shown in FIG. 3A, in the circuit board 4 according to this embodiment, the second inorganic insulating portion 7b2 made of the same material as the second inorganic insulating particles 11b is interposed between the second resin insulating portion 7b1 and the second penetrating conductor 8b. Therefore, similar to the above-described first inorganic insulating portion 7a2, insulating properties between the second insulating layer 7b and the second penetrating conductor 8b can be improved.

Since the second penetrating conductor 8b is formed into the column shape (tapered shape) such that its cross-section area along the planar direction of the circuit board 4 decreases toward the core board 5, in the case where heat is applied to the circuit board 4, stress caused by a difference in thermal expansion rate in the thickness direction between the second penetrating conductor 8b and the second insulating layer 7b is likely to concentrate on the end portion having the small cross-section area in the second penetrating conductor 8b. However, when the second inorganic insulating portion 7b2 is interposed between the second resin insulating portion 7b1 and the second penetrating conductor 8b, the second inorganic insulating portion 7b2 having the small thermal expansion rate in the thickness direction absorbs a difference in thermal expansion rate between the second penetrating conductor 8b and the second insulating layer 7b in the thickness direction, thus, the stress applied to the end portion having the small cross-section area in the second penetrating conductor 8b can be released, and a crack due to the stress can be prevented.

As shown in FIGS. 3A and 3B, the second inorganic insulating portion 7b2 has the groove portions G, the concave portions C, the voids V, and protruding portions 7b2p similar to the above-described first inorganic insulating portion 7a2.

Thus, the above-described structure 1 implements a desired function by driving or controlling the electronic component 2 based on a power supply and a signal supplied through the circuit board 4.

Next, a method for producing the above-described structure 1 is described.

(Production of Core Board)

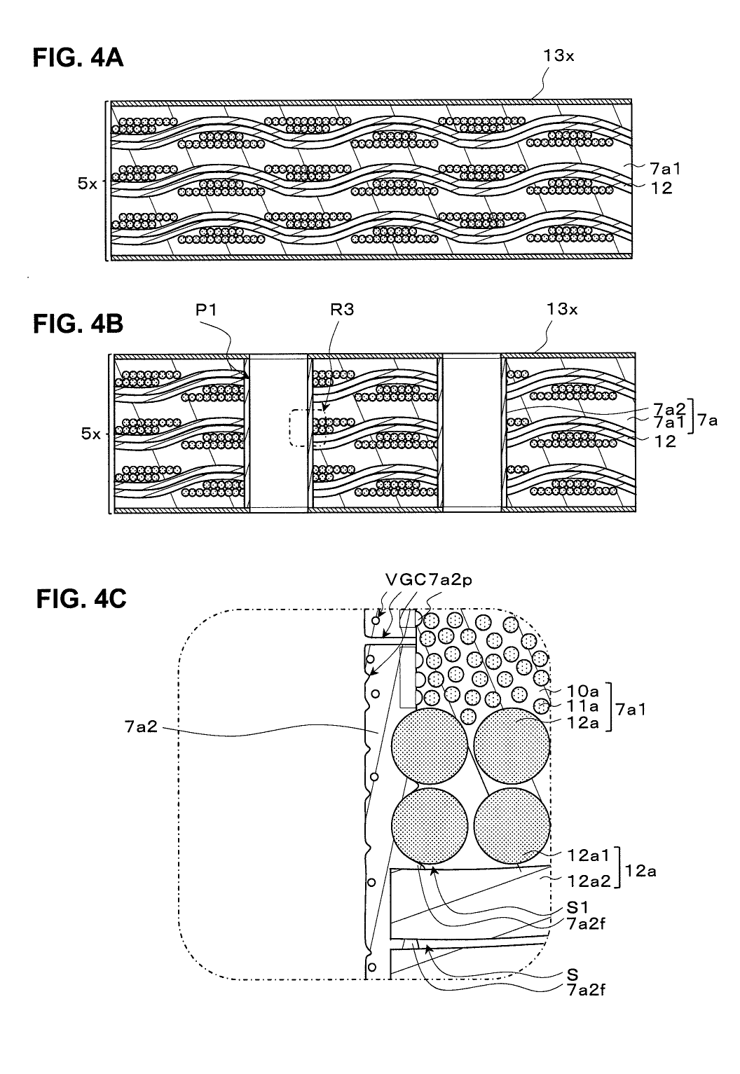

(1) As shown in FIG. 4A, a copper-clad laminate 5x is prepared such that the first insulating layer 7a composed of the first resin insulating portion 7a1 is formed, and a copper foil 13x is arranged on the upper and lower sides of the first insulating layer 7a. More specifically, it is prepared as follows.

A first insulating layer precursor is formed by laminating a plurality of resin sheets including the uncured resin material 10a, the first inorganic insulating particles 11a, and the fiber material 12, a laminated body is formed by laminating the copper foil 13x on the upper and lower sides of the first insulating layer precursor, and the first resin insulating portion 7a1 is formed by heating and pressurizing the laminated body in the thickness direction to thermally cure the first resin material 10a, whereby the above-described copper-clad laminate 5x is produced. In addition, the uncured state is in A-stage or B-stage in conformity with ISO472:1999.

Here, as described below, in order to form the first inorganic insulating portion 7a2 in step (2), in the first resin insulating portion 7a1, the first resin material 10a contains 50% by volume to 85% by volume of the first inorganic insulating particles 11a.

(2) As shown in FIGS. 4B and 4C, the first penetrating hole P1 is formed in the copper-clad laminate 5x, and the first inorganic insulating portion 7a2 forms the inner wall of the first penetrating hole P1. More specifically, they are formed as follows.

The first penetrating hole P1 is formed so as to penetrate the first resin insulating portion 7a1 in the thickness direction by irradiating the copper-clad laminate 5x with laser beam.

When the penetrating hole is formed by the irradiation of the laser beam, in some cases, the first inorganic insulating particle 11a is separated from the penetrating hole because the first resin material 10a coating the first inorganic insulating particle 11a exposed to the penetrating hole surface is rapidly thermally decomposed by heat energy of the laser beam.

Meanwhile, in the method for producing the circuit board 4 according to this embodiment, by setting a condition of the laser beam as follows when the first penetrating hole P1 is formed, the first inorganic insulating particles 11a can be melted to form the first inorganic insulating portion 7a2.

That is, YAG laser is selected as the laser beam, a wavelength of the laser beam is set at 200 nm to 380 nm, energy per pulse (shot) of the laser beam is set at 100 μJ to 1000 μJ, a pulse width of the laser beam is set at 5 ns (nano second) to 150 ns, and the number of shots of the laser beam is set at 100 to 1500.

Thus, the energy per pulse is small and the irradiation time is short. When the penetrating hole is formed by the irradiation of the pulse of the laser beam, the penetrating hole surface is heated and the energy of the laser beam is not likely to be transferred to the first resin material 10a. As a result, the first resin material 10a is not likely to be thermally decomposed. The first resin material 10a maintains adhesion with the first inorganic insulating particles 11a. Therefore, the first inorganic insulating particles 11a are likely to remain on the penetrating hole surface. Under such a condition, the first inorganic insulating particles 11a are irradiated with the pulse of the laser beam many times. Thus, the first inorganic insulating particles 11a can be melted.

The energy per pulse of the laser beam is preferably set at 100 μJ or more, which is enough to melt the first inorganic insulating particles 11a.

In the step (1), in the first resin insulating portion 7a1, the first resin material 10a contains 50% by volume to 85% by volume of the first inorganic insulating particles 11a, and the density of the first inorganic insulating particles 11a is set high in the first resin material 10a. Thus, the melted first inorganic insulating particles 11a form the first inorganic insulating portion 7a2.

Here, the pulse of the laser beam is preferably emitted intermittently. That is, it is preferable to repeat the irradiation at intervals such that the pulse of the laser beam is emitted continuously several times, and then the pulse of the laser beam is emitted continuously several times again after an interval. As a result, since the irradiation of the pulse of the laser beam is performed at intervals, the inside of the penetrating hole is less likely to be overheated. Thus, the energy of the laser beam is not likely to be transferred to the first resin material 10a and the first resin material 10a in vicinity of the penetrating hole surface is less likely to be thermally decomposed. In addition, the irradiation of the pulse of the laser beam is repeated such that five shots are emitted, and then next five shots are emitted after an interval, for example.

While the first inorganic insulating portion 7a2 is formed, the thermally decomposed first resin material generates gas such as carbon dioxide or water vapor, and the gas as a bubble moves in the melted first inorganic insulating particles 11a toward the inner side of the penetrating hole and it is emitted from the first inorganic insulating particle 11a. During this process, when such bubbles remain in the first inorganic insulating portion 7a2, the voids V are formed, and when trace remains after the emission from the first inorganic insulating portion 7a2, the concave portion C is formed. Thus, the voids V have the spherical shape and arranged more on the side of the first penetrating conductor 8a, and the concave portion C has a circular opening on the first boundary surface of the first inorganic insulating portion 7a2.

After the irradiation of the laser beam, a part of the first inorganic insulating particle 11a is melted while other part of the first inorganic insulating particle 11a remains unmelted. The unmelted part forms the protruding portion 7a2p. Thus, the protruding portion 7a2p protrudes toward the first resin insulating portion 7a1 and has a part of the shape of the first inorganic insulating particle 11a.

After the first inorganic insulating portion 7a2 has been formed, the heat of the laser beam is transferred, and the first insulating layer 7a is heated. At this time, since the thermal expansion rate of the first inorganic insulating portion 7a2 in the thickness direction of the first insulating layer 7a is smaller than that of the first resin insulating portion 7a1, tensile stress in the thickness direction of the first insulating layer 7a is applied to the first inorganic insulating portion 7a2, whereby the groove portion G is formed. Thus, the groove portion G penetrates the first inorganic insulating portion 7a2 from the first penetrating conductor 8a toward the first resin insulating portion 7a1, and elongates in the circumferential direction.

The fact that the first inorganic insulating particles 11a are connected to each other to form the first inorganic insulating portion 7a2 can be confirmed by cutting the circuit board 4 in the thickness direction, polishing the cut surface with argon ion gas, observing the cut surface with the field-emission electron microscope, and confirming that a trace of a boundary of the spherical first inorganic insulating particle 11a is left or the spherical protruding portion 7a2p is formed in a part of the first inorganic insulating portion 7a2, based on a difference in density of the inorganic insulating material. This confirmation method is also applicable to the second inorganic insulating portion 7b2.

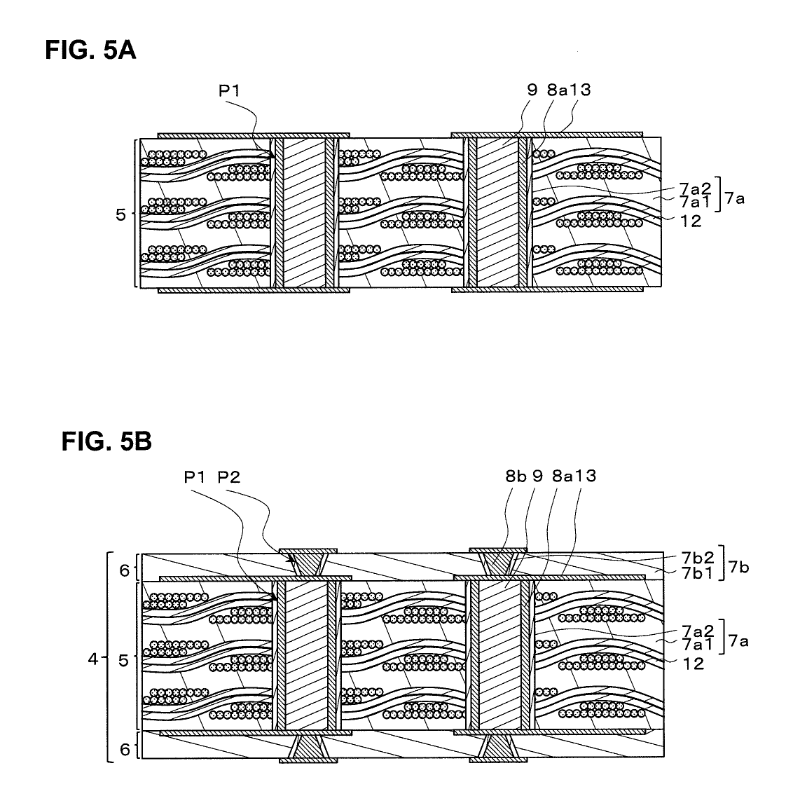

(3) As shown in FIG. 5A, the core board 5 is produced by forming the first penetrating conductor 8a, the insulator 9, and conductive layer 13. More specifically, it is produced as follows.

First, the conductive material is deposited on the inner wall of the first penetrating hole P1 by a method such as non-electrolytic plating, vapor deposition, CVD, or sputtering, to form the cylindrical first penetrating conductor 8a. At this time, the concave portion C and the groove portion G of the first inorganic insulating portion 7a2 is filled with the conductive material. In addition, the conductive material layer is formed by depositing the conductive material on the upper surface and the lower surface of the first insulating layer 7a. Then, the insulator 9 is formed by filling in the inner side of the cylindrical first penetrating conductor 8a with a resin material. Then, the conductive layer 13 is formed by patterning the conductive material layer by conventionally-known photolithography, or etching after depositing the conductive material on the exposed portion of the insulator 9.

Thus, the core board 5 is produced.

(Production of Circuit Board)

(4) As shown in FIG. 5B, the circuit board 4 is produced by forming a pair of buildup portions 6 on both sides of the core board 5. More specifically, it is produced as follows.

First, an uncured resin is arranged on the conductive layer 13, and the resin is heated so as to adhere thereto in a fluid state and further heated to be hardened, so that the second resin insulating portion 7b1 is formed on the conductive layer 13. Then, similar to the step (2), while the second inorganic insulating portion 7b2 is formed, the second penetrating hole P2 is formed in the second insulating layer 7b, and at least one part of the conductive layer 13 is exposed to the inner side of the second penetrating hole P2. Then, by a semi-additive method, subtractive method, or full-additive method, the second penetrating conductor 8b is formed in the second penetrating hole P2, and the conductive layer 13 is formed on the upper surface of the second insulating layer 7b.

Thus, the circuit board 4 can be produced. In addition, by repeating these steps, the second insulating layers 7b and the conductive layers 13 can be multilayered in the buildup portion 6.

(Production of Circuit Board)

(5) The bump 3 is formed on the upper surface of the conductive layer 13 serving as the uppermost layer, and the electronic component 2 is mounted to the circuit board 4 through the bump 3 by flip chip bonding.

As described above, the structure 1 shown in FIG. 1 can be produce.

Although the present invention has been fully described in connection with embodiments thereof with reference to the accompanying drawings, it is to be noted that various changes and modifications will become apparent to those skilled in the art. Such changes and modifications are to be understood as being included within the scope of the present invention as defined by the appended claims.

For example, in the above embodiments, capacitor may be used as the electronic component.

Although the semiconductor element is used as the electronic component in the above embodiments, it is understood that the semiconductor element is one example of the electronic component. Other types of the electronic component may include a capacitor.

Although the electronic component is mounted to the circuit board by the flip chip bonding in the above embodiment, the electronic component may be mounted to the circuit board by other bonding method such as wire bonding.

In addition, although the buildup portion includes only one second insulating layer in the above embodiment, the buildup portion may include any number of second insulating layers.

In addition, although each of the first insulating layer and the second insulating layer has the inorganic insulating layer film in the above embodiment, at least one of the first insulating layer and the second insulating layer may have the inorganic insulating layer film, and the circuit board may have only the first insulating layer or the second insulating layer.

In addition, although the first resin insulating portion includes the first resin material, the first inorganic insulating particles, and the fiber material in the above embodiment, it is not necessary that the fiber material is included in the first resin insulating portion as long as the first resin insulating portion includes the first resin material and the first inorganic insulating particles.

In addition, although the woven cloth is used as the fiber material in the above embodiment, it is understood that the woven cloth is one example of the fiber material. Other types of the fiber material may include fibers arranged in one direction, and unwoven cloth.

In addition, although the copper foil is used in the step (1) of the above embodiment, metal foil composed of metal material such as an iron-nickel alloy or iron-nickel-cobalt alloy may be used instead of the copper foil.

### Working Example

Hereinafter, while the present invention is described in detail with reference to working examples, the present invention is not limited to the following working examples, and a change and an embodiment without departing from the scope of the present invention may be included in the present invention.

(Evaluation Method)

A copper-clad laminate was produced by laminating copper foil on the upper and lower sides of a first insulating layer composed of a first resin insulating portion, and a first penetrating hole was formed by irradiating the copper-clad laminate with laser beam having conditions shown in Table 1. Then, a cross section provided by cutting the copper-clad laminate in a thickness direction and polishing was photographed with a field-emission electron microscope (JSM-7000F produced by JEOL Ltd.), and structures of the first insulating layer and the first penetrating hole were observed.

(Condition for Producing Copper-Clad Laminate)

First, a first resin layer precursor was formed by laminating four layers of resin sheets including an uncured first resin material, and first inorganic insulating particles shown in Table 1, and a fiber material composed of glass cloth, and a laminated body was formed by laminating copper foil on the upper and lower sides of the first resin layer precursor.

Next, the laminated body was heated and pressurized in a thickness direction under a condition that temperature: 185° C., pressure: 3 MPa, and time: 90 minutes, whereby the above copper-clad laminate was produced.

(Result)

In the working examples 1 and 2, the first inorganic insulating portion was formed on the inner wall of the first penetrating hole. Meanwhile, in the working example 3, the first inorganic insulating particles exposed to the inner wall of the first penetrating hole were melted but the first inorganic insulating portion was not in a film state. In addition, in the working example 4, the first inorganic insulating portion was formed in a part of the inner wall of the first penetrating hole but the exposed first inorganic insulating particles were not melted and the first inorganic insulating portion was not formed in the other part of the inner wall of the first penetrating hole. In the working examples 5 to 7, the first inorganic insulating particles exposed to the inner wall of the first penetrating hole were not melted and the first inorganic insulating portion was not formed. In the working example 8, the first inorganic insulating particles were not exposed to the inner wall of the first penetrating hole, and the first inorganic insulating portion was not formed.

TABLE 1

| | First resin | First inorganic insulating particle | | | laser beam irradiation condition | | | | |
|---|---|---|---|---|---|---|---|---|---|
| | material | Material | Particle | | | | Energy | Pulse | The number |
| Sample | Material name | name | diameter | Content | Kind | Wavelength | (per pulse) | width | of shots |
| 1 | Cyanate resin | Silicon oxide | 1.0 μm | 65% by volume | YAG laser | 355 nm | 110 μJ | 20 ns | 800 shots |
| 2 | Cyanate resin | Silicon oxide | 1.0 μm | 65% by volume | YAG laser | 355 nm | 140 μJ | 30 ns | 800 shots |
| 3 | Cyanate resin | Silicon oxide | 1.0 μm | 45% by volume | YAG laser | 355 nm | 110 μJ | 20 ns | 800 shots |
| 4 | Cyanate resin | Silicon oxide | 1.0 μm | 65% by volume | YAG laser | 266 nm | 40 μJ | 60 ns | 1200 shots |
| 5 | Cyanate resin | Silicon oxide | 1.0 μm | 65% by volume | Carbon dioxide | 9.3 μm | 22 mJ | 200 μs | 6 shots |
| | | | | | gas laser | | | | |
| 6 | Cyanate resin | Silicon oxide | 1.0 μm | 45% by volume | Carbon dioxide | 9.3 μm | 22 mJ | 200 μs | 6 shots |
| | | | | | gas laser | | | | |
| 7 | Epoxy resin | Silicon oxide | 1.0 μm | 20% by volume | Carbon dioxide | 9.3 μm | 22 mJ | 200 μs | 6 shots |
| | | | | | gas laser | | | | |
| 8 | Epoxy resin | Not used | Not used | Not used | Carbon dioxide | 9.3 μm | 22 mJ | 200 μs | 6 shots |
| | | | | | gas laser | | | | |

What is claimed is:

1. A circuit board comprising:
an insulating layer including a resin material, a plurality of inorganic insulating particles, and a penetrating hole; and
a penetrating conductor in the penetrating hole;
wherein the insulating layer includes a resin insulating portion having the plurality of inorganic insulating particles dispersed in the resin material, and an inorganic insulating portion interposed between the resin insulating portion and the penetrating conductor.

2. The circuit board according to claim 1, wherein
the inorganic insulating portion includes a groove portion penetrating the inorganic insulating portion from the penetrating conductor to the resin insulating portion and formed along circumferential direction of the penetrating hole, and
a part of the penetrating conductor fills in the groove portion.

3. The circuit board according to claim 2, wherein
the inorganic insulating portion includes a plurality of concave portions formed on a first boundary surface between the inorganic insulating portion and the penetrating conductor, and
a part of the penetrating conductor fills in the concave portion.

4. The circuit board according to claim 1, wherein
the inorganic insulating portion includes a plurality of voids, and more voids are disposed in a penetrating conductor side than in a resin insulating portion side.

5. The circuit board according to claim 1, wherein
the inorganic insulating portion includes a plurality of protruding portions having the inorganic insulating particle and formed on a second boundary surface between the inorganic insulating portion and the resin insulating portion, and
the protruding portion projects into the resin insulating portion and is covered with the resin material.

6. The circuit board according to claim 1, wherein
the insulating layer further includes a plurality of fibers disposed in the resin insulating portion and covered with the resin material, and
the inorganic insulating portion is interposed between the fibers and the penetrating conductor.

7. The circuit board according to claim 6, wherein
a part of the inorganic insulating portion is in a space between the adjacent fibers.

8. The circuit board according to claim 7, wherein
the plurality of fibers includes a first fiber and a second fiber adjacent to and perpendicular to the first fiber, and
the part of the inorganic insulating portion is in a space between the first fiber and the second fiber.

9. A structure comprising:
the circuit board according to claim 1, and
an electronic component electrically connected to the circuit board.

10. The circuit board according to claim 1, wherein
the inorganic insulating portion is formed of the same material as the plurality of inorganic insulating particles.

11. The circuit board according to claim 1, wherein
the inorganic insulating portion is made by melting a plurality of inorganic insulating particles.
